(19) United States
(12) Patent Application Publication
(10) Pub. No.: US 2009/0271649 A1
(43) Pub. Date: Oct. 29, 2009

(54) VOLTAGE REGULATOR PHASE SHEDDING

(75) Inventors: John Loffink, Austin, TX (US); George G. Richards, III, Round Rock, TX (US)

Correspondence Address: HAYNES AND BOONE, LLP;IP Section, 2323 Victory Avenue, Suite 700, Dallas, TX, 75219, US

(73) Assignee: DELL PRODUCTS L.P., Round Rock, TX (US)

(21) Appl. No.: 12/109,610

(22) Filed: Apr. 25, 2008

(51) Int. Cl. G06F 1/00; G11C 5/14

(52) U.S. Cl. 713/340; 365/227

(57) ABSTRACT

A voltage regulator phase shedding system includes one or more subsystems to inventory memory power requirements of an IHS component, calculate a calculated memory power consumption, compare the calculated memory power consumption to a predetermined table of values to determine which phases of the voltage regulator to turn on, apply system power, assert desired phases of the voltage regulator after power is applied to the voltage regulator, and enable the voltage regulator to operate the desired phases of the voltage regulator.

### BACKGROUND

The present disclosure relates generally to information handling systems, and more particularly to voltage regulator phase shedding.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

High Power DC to DC Voltage Regulators for IHSs are typically designed using multiple phases for more efficient power conversion. Recently, the technique of phase shedding has been promoted as a means to improve converter efficiency when less power is consumed. Dynamic phase shedding may require clear characterization of the anticipated slew rate requirements so that the transient response of the power device is not exceeded. Static phase shedding is a more simple problem to solve, but still may require a defined method for detecting the ability to phase shed and predicting the resultant power savings. However, the mechanism whereby the phases are shed is not defined.

Accordingly, it would be desirable to provide improved voltage regulator phase shedding.

### SUMMARY

According to one embodiment, a voltage regulator phase shedding system includes one or more subsystems to inventory memory power requirements of an IHS component, calculate a calculated memory power consumption, compare the calculated memory power consumption to a predetermined table of values to determine which phases of the voltage regulator to turn on, apply system power, assert desired phases of the voltage regulator after power is applied to the voltage regulator, and enable the voltage regulator to operate the desired phases of the voltage regulator.

### BRIEF DESCRIPTION OF THE DRAWINGS

FIG. 1 illustrates an embodiment of an information handling system (IHS).

FIG. 2 illustrates an embodiment of a method of voltage regulator phase shedding.

FIG. 3 illustrates an embodiment of a phase shedding efficiency chart with typical configurations mapped.

FIG. 4 illustrates an embodiment of power savings per memory voltage regulator from phase shedding with typical configurations mapped.

### DETAILED DESCRIPTION

For purposes of this disclosure, an IHS 100 includes any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an IHS 100 may be a personal computer, a network storage device, or any other suitable device and may vary in size, shape, performance, functionality, and price. The IHS 100 may include random access memory (RAM), one or more processing resources such as a central processing unit (CPU) or hardware or software control logic, read only memory (ROM), and/or other types of nonvolatile memory. Additional components of the IHS 100 may include one or more disk drives, one or more network ports for communicating with external devices as well as various input and output (I/O) devices, such as a keyboard, a mouse, and a video display. The IHS 100 may also include one or more buses operable to transmit communications between the various hardware components.

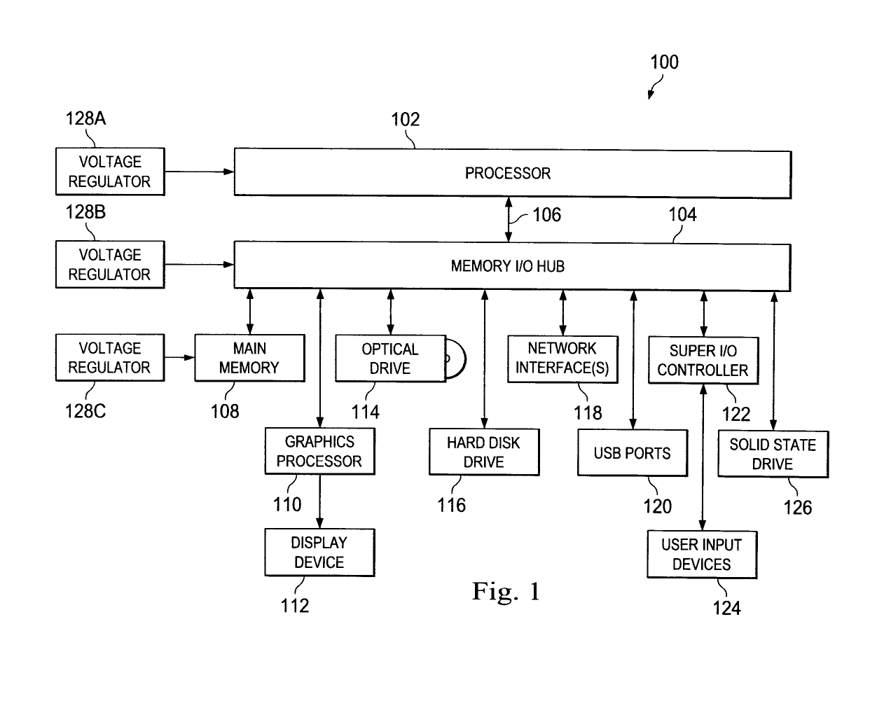

FIG. 1 is a block diagram of one IHS 100. The IHS 100 includes a processor 102 such as an Intel Xeon™ series processor or any other processor available. A memory I/O hub chipset 104 (comprising one or more integrated circuits) connects to processor 102 over a front-side bus 106. Memory I/O hub 104 provides the processor 102 with access to a variety of resources. Main memory 108 connects to memory I/O hub 104 over a memory or data bus. A graphics processor 110 also connects to memory I/O hub 104, allowing the graphics processor to communicate, e.g., with processor 102 and main memory 108. Graphics processor 110, in turn, provides display signals to a display device 112.

Other resources can also be coupled to the system through the memory I/O hub 104 using a data bus, including an optical drive 114 or other removable-media drive, one or more hard disk drives 116, one or more network interfaces 118, one or more Universal Serial Bus (USB) ports 120, and a super I/O controller 122 to provide access to user input devices 124, etc. The IHS 100 may also include a solid state drive (SSDs) 126 in place of, or in addition to main memory 108, the optical drive 114, and/or a hard disk drive 116. It is understood that any or all of the drive devices 114, 116, and 126 may be located locally with the IHS 100, located remotely from the IHS 100, and/or they may be virtual with respect to the IHS 100. In an embodiment, a voltage regulator 128A, 128B, and/or 128C (collectively 128) may couple with the processor 102, the memory hub 104, the main memory 108, and/or a variety of other components to regulate voltage to power the respective components.

Not all IHSs 100 include each of the components shown in FIG. 1, and other components not shown may exist. Furthermore, some components shown as separate may exist in an integrated package or be integrated in a common integrated circuit with other components, for example, the processor 102 and the memory I/O hub 104 can be combined together. As can be appreciated, many systems are expandable, and include or can include a variety of components, including redundant or parallel resources.

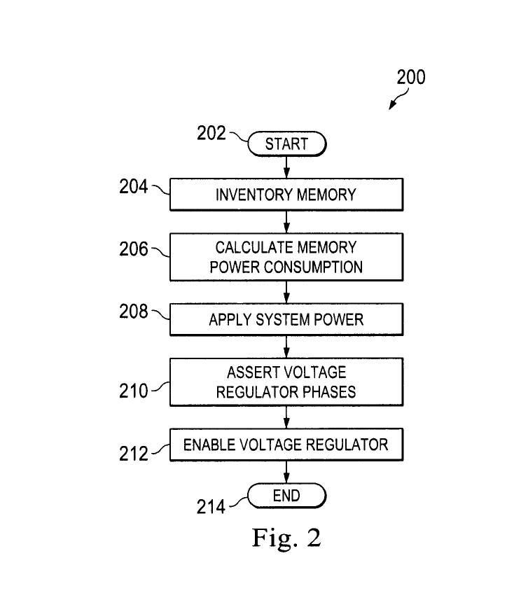

FIG. 2 illustrates an embodiment of a method 200 of voltage regulator phase shedding. The method 200 begins at block 202 where the IHS 100 may be in a stand by mode. The method 200 then proceeds to block 204 where a baseboard management controller or other type of controller uses information in a serial presence detect for each memory module to provide a detailed memory power inventory based upon memory configuration and parameters. A baseboard management controller is generally understood in the art as a microcontroller included on a motherboard of an IHS 100 to manage the interface between a system management software and the platform hardware. A serial presence detect is generally understood in the art as a standardized way to automatically access information about memory modules, such as main memory 108. A memory module may be what is commonly known in the art as a memory module populated on the system memory 108 directly, a single in-line memory module (SIMM), dual in-line memory module (DIMM) or other type of memory module. The method 200 then proceeds to block 206 where the method 200 calculates memory power consumption based on information received by the serial presence detect and compares the calculated memory power consumption with a predefined table of values for voltage regulator and/or a maximum capacity per number of voltage regulator phases. The method 200 then proceeds to block 208 where the method 200 then applies electrical power to the system. The method 200 then proceeds to block 210 where the method 200 asserts the desired voltage regulator phases to the voltage regulator 128 as calculated in block 206. The method 200 then proceeds to block 212 where the method 200 enables the voltage regulator 128 to operate using the phases asserted in block 210. The method 200 then proceeds to block 214 where the method 200 ends and the IHS 100 operates having the voltage regulator 128 operate using the desired phases.

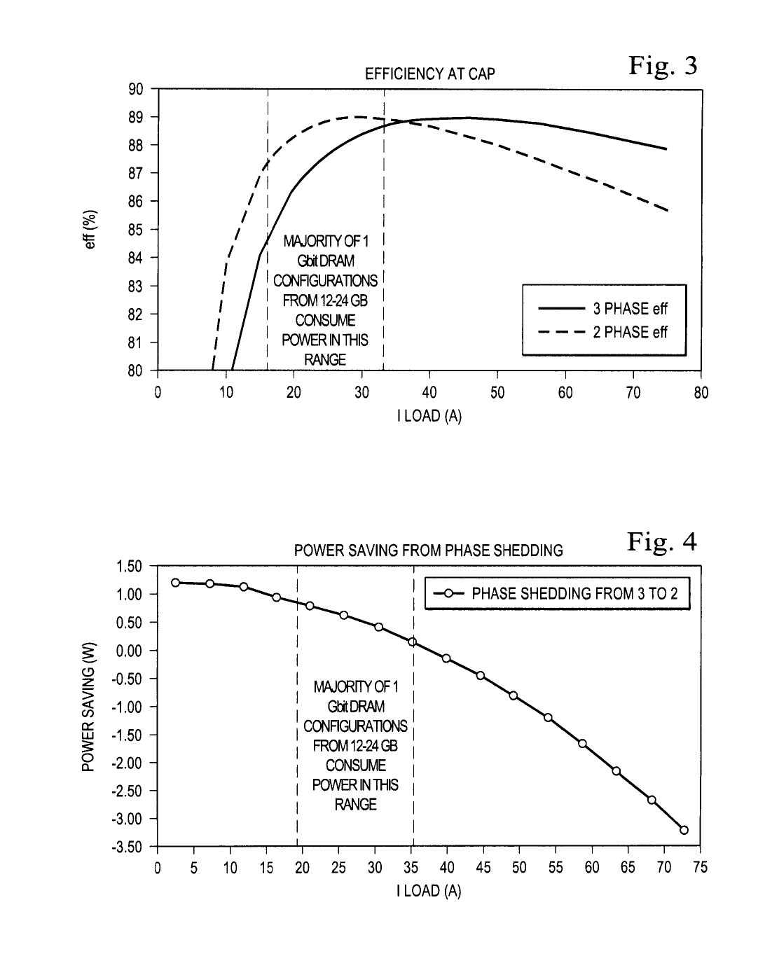

FIG. 3 illustrates an embodiment of a phase shedding efficiency chart with typical configurations mapped. This chart shows the efficiency range for 2 and 3 phase operation. As shown, the majority of systems may lie in the range where 2 phase operation is more efficient than 3 phase operation.

FIG. 4 illustrates an embodiment of power savings per memory voltage regulator from phase shedding with typical configurations mapped. This chart shows the actual power savings per memory voltage regulator. Thus, if there are two voltage regulators for a 2 socket system, the power savings may be doubled.

In an embodiment, the proposed solution may use information in the Serial Presence Detect for each memory DIMM to provide a detailed memory power inventory based upon memory configuration and parameters. The details vary for each type, such as, DDR2, DDR3 and FBD as different information is defined for each serial presence detect format. The method for DDR3 is summarized below for simplicity and it is important to remember that many variations exist depending on the accuracy level desired. Additionally, a second method exists for FBD using DTBytes, which show current consumption of the memory based upon different operating modes. These values may be used to calculate the memory power on a per DIMM supplier basis.

In an embodiment, the memory power inventory may be completed by the baseboard memory controller through access to memory serial presence detect (SPD), parallel presence detect (PPD), or an in-system format via a memory channel while the system is in standby. The memory power consumption may then be calculated based upon SDRAM capacity (serial presence detect byte 4 bits 3-0), primary bus width (SPD byte 8 bit 2-0), SRAM width (SPD byte 7 bits 2-0), number of ranks (SPD byte 7 bits 5-3), speed (derived from SPC bytes 11 and 12) and DIMMs per channel may be used to calculate the maximum power consumption for the memory module. DIMMS per channel may be determined based upon presence of memory channels to those address. These values generate a pointer to a table with the pre-calculated power numbers. Further refinement of inventory such power per vendor, die revision and other parameters are possible. In embodiment, a basic input/output system (BIOS) system may calculate memory power after a system boot-up and apply phase shedding after power is applied to a voltage regulator 128.

The calculated maximum power may be compared to a table of voltage regulator efficiency and maximum capacity per number of phases. This is used to determine which phases of the voltage regulator 128 to turn on. In the case of our initial implementation, only one level of phase shedding may be provided so this determination is greatly simplified.

Next, system power is applied to the IHS 100. Through power management bus or through sideband phase shed enable signals the baseboard management controller may assert the desired phases on the Memory voltage regulator 128, after power is applied to the voltage regulator but before the voltage regulator is enabled. Then, the memory voltage regulator 128 is turned on, and a normal system boot process continues. After the boot process is completed, the system runs at this improved efficiency model from here forward. In an embodiment, enhancements to this disclosure include shedding to multiple phase levels.

One aspect of this disclosure is the combination of the memory power inventory process, and assessment of typical configuration, to design the system for the most efficient operating point. In addition to static phase shedding, the same or a similar power inventory process may be applied to setting the cap or limit for dynamic phase shedding controls, thereby enabling the controller to understand the necessary range for phase shedding commands and adjusting the dynamic behavior only within that range. An example implementation may use power management bus commands to the voltage regulator to set the power limit based upon configuration. The voltage regulator or other phase shedding controller may then adjust the phase shedding within the desired range. Constraining the range of dynamic phase shedding may allow decisions about optimization of the control, such as dynamic constraints that might otherwise limit the dynamic behavior.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

1. A voltage regulator phase shedding system comprising one or more subsystems to:
inventory memory power requirements of a memory module;
calculate a calculated memory power consumption;
compare the calculated memory power consumption to a predetermined table of values to determine which phases of the voltage regulator to turn on;
apply system power;
assert desired phases of the voltage regulator after power is applied to the voltage regulator, but before the voltage regulator is enabled; and
enable the voltage regulator to operate the desired phases of the voltage regulator.

2. The system of claim 1, wherein the inventory includes a memory configuration and memory parameters.

3. The system of claim 1, wherein the memory module is a memory module populated on the system memory directly, a single in-line memory module (SIMM), or a dual in-line memory module (DIMM).

4. The system of claim 3, wherein the DIMM is a fully buffered DIMM.

5. The system of claim 1, wherein the memory power requirements are of double-data-rate memory.

6. The system of claim 1, wherein the inventory is performed using a serial presence detect (SPD) format, a parallel presence detect (PPD) format, or an in-system format via a memory channel.

7. The system of claim 6, wherein the inventory is performed by a baseboard management controller (BMC) or a basic input/output system (BIOS).

8. The system of claim 1, wherein the inventory is performed when the memory module is in a standby mode.

9. The system of claim 1, wherein the memory power consumption is calculated using one or more of the parameters consisting of memory module capacity, primary bus width, synchronous random access memory (SRAM) width, number or ranks, speed, vendor produce requirements and dual in-line memory modules per channel.

10. An information handling system (IHS) comprising:
a processor;
a memory coupled with the processor; and
one or more voltage regulator phase shedding system to adjust power to the memory, the voltage regulator phase shedding system comprising one or more subsystems to:
inventory memory power requirements of a memory module;
calculate a calculated memory power consumption;
compare the calculated memory power consumption to a predetermined table of values to determine which phases of the voltage regulator to turn on;
apply system power;
assert desired phases of the voltage regulator after power is applied to the voltage regulator, but before the voltage regulator is enabled; and
enable the voltage regulator to operate the desired phases of the voltage regulator.

11. The IHS of claim 10, wherein the inventory includes a memory configuration and memory parameters.

12. The IHS of claim 10, wherein the memory module is a memory module populated on the system memory directly, a single in-line memory module (SIMM), or a dual in-line memory module (DIMM).

13. The IHS of claim 12, wherein the DIMM is a fully buffered DIMM.

14. The IHS of claim 10, wherein the memory power requirements are of double-data-rate memory.

15. The IHS of claim 10, wherein the inventory is performed using a serial presence detect (SPD) format, a parallel presence detect (PPD) format, or an in-system format via a memory channel.

16. The IHS of claim 15, wherein the inventory is performed by a baseboard management controller (BMC) or a basic input/output system (BIOS).

17. The IHS of claim 10, wherein the inventory is performed when the memory module is in a standby mode.

18. The IHS of claim 10, wherein the memory power consumption is calculated using one or more of the parameters consisting of memory module capacity, primary bus width, synchronous random access memory (SRAM) width, number or ranks, speed, vendor product requirements and dual in-line memory modules per channel.

19. A method of shedding phases for a voltage regulator comprising:
inventorying memory power requirements of a memory module while in a standby mode;
calculating a calculated memory power consumption;
comparing the calculated memory power consumption to a predetermined table of values to determine which phases of the voltage regulator to turn on;
applying system power;
asserting desired phases of the voltage regulator after power is applied to the voltage regulator, but before the voltage regulator is enabled; and
enabling the voltage regulator to operate the desired phases of the voltage regulator.

20. The method of claim 19, wherein the memory power consumption is calculated using one or more of the parameters comprising memory module capacity, primary bus width, synchronous random access memory (SRAM) width, number or ranks, speed, and dual in-line memory modules per channel.

21. A method of shedding phases for a voltage regulator comprising:
extracting a power consumption value from a memory module, where the power consumption value has been preprogrammed into the memory module;
comparing the memory power consumption value to a predetermined table of values to determine which phases of the voltage regulator to turn on;
applying system power;
asserting desired phases of the voltage regulator after power is applied to the voltage regulator, but before the voltage regulator is enabled; and
enabling the voltage regulator to operate the desired phases of the voltage regulator.

22. A voltage regulator phase shedding system comprising one or more subsystems to:
inventory power requirements of an information handling system (IHS) component;
calculate a calculated component power consumption;
compare the calculated component power consumption to a predetermined table of values to determine which phases of the voltage regulator to turn on;
apply system power;
assert desired phases of the voltage regulator after power is applied to the voltage regulator, but before the voltage regulator is enabled; and
enable the voltage regulator to operate the desired phases of the voltage regulator.

23. The voltage regulator phase shedding system of claim 22, wherein the IHS component is a central processing unit (CPU), an input/output (I/O) device, a system management device, or a graphics device.
